(19) United States
(12) Patent Application Publication
(10) Pub. No.: US 2002/0189543 A1
(43) Pub. Date: Dec. 19, 2002

(54) High pressure processing chamber for semiconductor substrate including flow enhancing features

(76) Inventors: Maximilian A. Biberger, Scottsdale, AZ (US); Frederick P. Layman, Fremont, CA (US); Thomas R. Sutton, Mesa, AZ (US)

Correspondence Address: HAVERSTOCK & OWENS LLP, 162 North Wolfe Road, Sunnyvale, CA, 94086, US

(21) Appl. No.: 10/121,791

(22) Filed: Apr. 10, 2002

Related U.S. Application Data
(60) Provisional application No. 60/283,132, filed on Apr. 10, 2001.

(51) Int. Cl. C23F 1/00; C23C 16/00

(52) U.S. Cl. 118/715; 156/345.33

(57) ABSTRACT

A high pressure chamber for processing of a semiconductor substrate comprises a high pressure processing cavity, a plurality of injection nozzles, and first and second outlet ports. The high pressure processing cavity holds the semiconductor substrate during high pressure processing. The plurality of injection nozzles are oriented into the high pressure processing cavity at a vortex angle and are operable to produce a vortex over a surface of the semiconductor substrate. The first and second outlet ports are located proximate to a center of the plurality of injection nozzles and are operable in a first time segment to provide an operating outlet out of the first outlet port and operable in a second time segment to provide the operating outlet out of the second outlet port. In an alternative embodiment, an upper surface of the high pressure processing cavity comprises a height variation. The height variation produces more uniform molecular speeds for a process fluid flowing over the semiconductor substrate.

### RELATED APPLICATIONS

This application claims priority from U.S. Provisional Patent Application No. 60/283,132, filed on Apr. 10, 2001, which is incorporated by reference.

### FIELD OF THE INVENTION

This invention relates to the field of high pressure processing. More particularly, this invention relates to the field of high pressure processing of a semiconductor substrate.

### BACKGROUND OF THE INVENTION

Processing of semiconductor substrates presents unique problems not associated with processing of other workpieces. Typically, the semiconductor processing begins with a silicon wafer. The semiconductor processing starts with doping of the silicon wafer to produce transistors. Next, the semiconductor processing continues with deposition of metal and dielectric layers interspersed with etching of lines and vias to produce transistor contacts and interconnect structures. Ultimately in the semiconductor processing, the transistors, the transistor contacts, and the interconnects form integrated circuits.

A critical processing requirement for the processing of the semiconductor substrate is cleanliness. Much of semiconductor processing takes place in vacuum, which is an inherently clean environment. Other semiconductor processing takes place in a wet process at atmospheric pressure, which because of a rinsing nature of the wet process is an inherently clean process. For example, removal of photoresist and photoresist residue subsequent to etching of the lines and the vias uses plasma ashing, a vacuum process, followed by stripping in a stripper bath, a wet process.

Other critical processing requirements for the processing of the semiconductor substrates include throughput and reliability. Production processing of the semiconductor substrates takes place in a semiconductor fabrication facility. The semiconductor fabrication facility requires a large capital outlay for processing equipment, for the facility itself, and for a staff to run it. In order to recoup these expenses and generate a sufficient income from the facility, the processing equipment requires a throughput of a sufficient number of the wafers in a period of time. The processing equipment must also promote a reliable process in order to ensure continued revenue from the facility.

Until recently, the plasma ashing and the stripper bath were found sufficient for the removal of the photoresist and the photoresist residue in the semiconductor processing. However, recent advancements for the integrated circuits include etch feature critical dimensions below dimensions with sufficient structure to withstand the stripper bath and low dielectric constant materials which cannot withstand an oxygen environment of the plasma ashing.

Recently, interest has developed in replacing the plasma ashing and the stripper bath for the removal of the photoresist and the photoresist residue with a supercritical process. However, high pressure processing chambers of existing supercritical processing systems are not appropriate to meet the unique needs of the semiconductor processing requirements. In particular, high pressure chamber of existing supercritical processing systems do not provide a flow speed adequate to remove particulate matter from a surface of the semiconductor wafer.

What is needed is a high pressure processing chamber for semiconductor processing which provides adequate flow speed over a surface of a semiconductor substrate.

### SUMMARY OF THE INVENTION

The present invention is a high pressure chamber for processing of a semiconductor substrate comprising a high pressure processing cavity, a plurality of injection nozzles, and first and second outlet ports. The high pressure processing cavity holds the semiconductor substrate during high pressure processing. The plurality of injection nozzles are oriented into the high pressure processing cavity at a vortex angle and are operable to produce a vortex over a surface of the semiconductor substrate. The first and second outlet ports are located proximate to a center of the plurality of injection nozzles and are operable in a first time segment to provide an operating outlet out of the first outlet port and operable in a second time segment to provide the operating outlet out of the second outlet port.

In an alternative embodiment of the present invention, an upper surface of the high pressure processing cavity comprises a height variation. The height variation produces more uniform molecular speeds for a process fluid flowing over the semiconductor substrate.

### BRIEF DESCRIPTION OF THE DRAWINGS

FIG. 1 illustrates a pressure chamber frame of the present invention.

FIG. 2 illustrates a first alternative pressure chamber of the present invention.

FIG. 3 illustrates a cross-section of the first alternative pressure chamber of the present invention.

FIGS. 4A and 4B illustrate a spacer/injection ring of the present invention.

FIG. 5 illustrates a wafer cavity and a two port outlet of the present invention.

FIG. 6 illustrates a supercritical processing module and a second alternative pressure chamber of the present invention.

FIG. 7 illustrates the wafer cavity of the present invention.

FIGS. 8A-8C illustrate first through third alternative wafer cavities of the present invention.

FIG. 9 illustrates the preferred pressure chamber of the present invention.

FIGS. 10A and 10B illustrate an upper cavity plate/injection ring of the present invention.

### DETAILED DESCRIPTION OF THE INVENTION

The preferred pressure chamber of the present invention is preferably used for supercritical processing of a semiconductor wafer. Preferably, the preferred pressure chamber forms part of a supercritical processing module. Preferably, the supercritical processing module is used to remove materials such as photoresist, photoresist residue, and etch residue from the semiconductor wafer. Alternatively, the supercritical processing module is used for other supercritical processing of the semiconductor wafer, such as photoresist development.

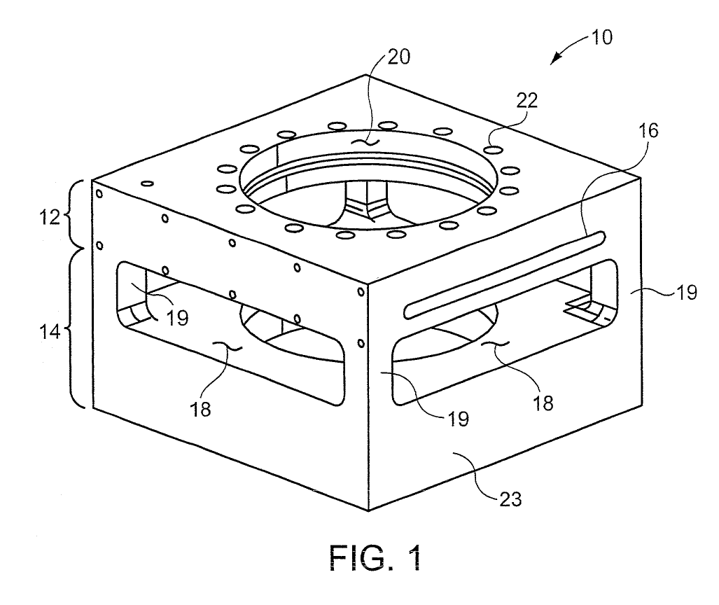

A pressure chamber frame of the present invention is illustrated in FIG. 1. The pressure chamber frame 10 includes a pressure chamber housing portion 12, a hydraulic actuation portion 14, a wafer slit 16, windows 18, posts 19, a top opening 20, and top bolt holes 22. The wafer slit 16 is preferably sized for a 300 mm wafer. Alternatively, the wafer slit 16 is sized for a larger or a smaller wafer. Further alternatively, the wafer slit 16 is sized for a semiconductor substrate other than a wafer, such as a puck.

The hydraulic actuation portion 14 of the pressure chamber frame 10 includes the windows 18, which provide access for assembly and disassembly of the preferred pressure chamber. Preferably, there are four of the windows 18, which are located on sides of the pressure chamber frame 10. Preferably, each of the windows 18 are framed on their sides by two of the posts 19, on their top by the pressure chamber housing portion 12, and on their bottom by a base 23. The bolt holes 22 of the pressure chamber housing portion 12 are for bolting a top lid to the pressure chamber frame 10.

Before describing the preferred pressure chamber of the present invention, first and second alternative pressure chambers of the present invention are described in order to more simply introduce aspects of the present invention.

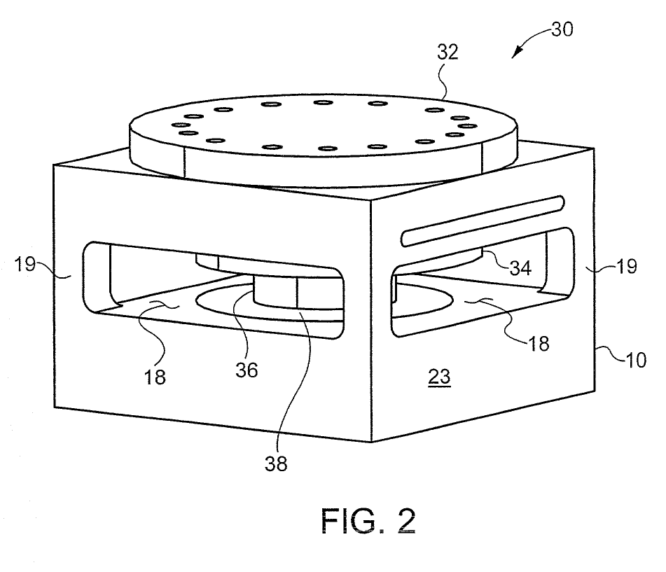

The first alternative pressure chamber of the present invention is illustrated in FIG. 2. The first alternative pressure chamber 30 includes the pressure chamber frame 10, the top lid 32, a wafer platen 34, a cylinder 36, and a sealing plate 38. The top lid 32 is coupled to the pressure chamber frame 10, preferably by bolts (not shown). The wafer platen 34 is coupled to the cylinder 36. The cylinder 36 is coupled to a piston (not shown). The sealing plate 38 seals the piston from atmosphere.

It will be readily apparent to one skilled in the art that fasteners couple the wafer platen 34 to the cylinder 36, couple the cylinder 36 to the piston, and couple the sealing plate 38 to the pressure chamber frame 10. Further, it will be readily apparent to one skilled in the art that the bolts which preferably couple the top lid 32 to the pressure chamber frame 10 can be replaced by other fasteners, such as by screws or by threading the pressure chamber frame 10 and the top lid 32.

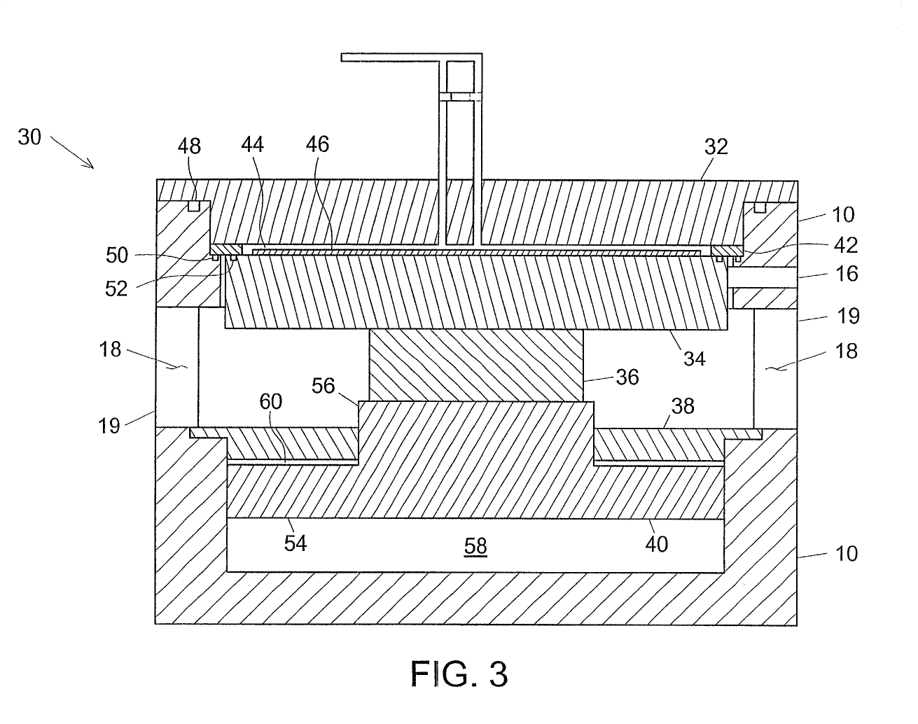

A cross-sectional view of the first alternative pressure chamber 30 in a closed configuration is illustrated in FIG. 3. The first alternative pressure chamber 30 includes the pressure chamber frame 10, the top lid 32, the wafer platen 34, the cylinder 36, the sealing plate 38, the piston 40, and a spacer/injection ring 42. Preferably, the pressure chamber frame 10, the top lid 32, the wafer platen 34, the cylinder 36, the sealing plate 38, the piston 40, and the spacer/injection ring 42 comprise stainless steel. The spacer/injection ring 42, the top lid 32, and the wafer platen 34 form a wafer cavity 44. The wafer cavity 44 is preferably sealed with first, second, and third o-rings (not shown) located in first, second, and third o-ring grooves, 48, 50, and 52. The pressure chamber frame 10 and the sealing plate 38 enclose a piston body 54 leaving a piston neck 56 extending through the sealing plate 38. The piston neck 56 couples to the cylinder 36, which in turn couples to the wafer platen 34.

The pressure chamber frame 10 and the piston body 56 form a hydraulic cavity 58 below the piston body 56. The pressure chamber frame 10, the sealing plate 38, the piston body 54, and the piston neck 56 just above the piston body 54 form a pneumatic cavity 60 between the piston body 54 and the sealing plate 38.

It will be readily apparent to one skilled in the art that a piston seal between the piston body 54 and the pressure chamber frame 10 isolates the hydraulic cavity 58 from the pneumatic cavity 60. Further, it will be readily apparent to one skilled in the art that a neck seal, between the piston neck 56 and the sealing plate 38, and a plate seal, between the sealing plate 38 and the pressure chamber frame 10, isolate the pneumatic cavity 60 from atmosphere. Moreover, it will be readily apparent to one skilled in the art that in operation hydraulic and pneumatic fluid systems, both of which are well known in the art, are coupled to the hydraulic cavity 58 and the pneumatic cavity 60, respectively.

In the supercritical processing, the semiconductor wafer 46 occupies the wafer cavity 44 where a supercritical fluid is preferably used in conjunction with a solvent to remove the photoresist from the semiconductor wafer 46. Preferably, the wafer platen 34 comprises a vacuum chuck, which holds the semiconductor wafer 46 during the semiconductor processing. After the supercritical processing and venting of the wafer cavity 44 to atmospheric pressure, hydraulic fluid within the hydraulic cavity 58 is depressurized while the pneumatic cavity 60 is slightly pressurized with a gas, which moves the piston 40 down. This lowers the wafer platen 34 so that the semiconductor wafer 46 is adjacent to the slit 16. The wafer 46 is then removed through the slit 16. Preferably, the semiconductor wafer is removed by a robot (not shown). Alternatively, the semiconductor wafer 46 is removed by a technician.

A second semiconductor wafer is then loaded through the slit 16 and onto the wafer platen 34. Next, the pneumatic cavity 60 is vented to atmospheric pressure while the hydraulic cavity 58 is pressurized with the hydraulic fluid, which drives the wafer platen 34 into the spacer/injection ring 42, which reforms the wafer cavity 44. The wafer cavity 44 is then pressurized, and the supercritical fluid and the solvent remove the photoresist from the second wafer.

It will be readily apparent to one skilled in the art that during the supercritical processing the hydraulic fluid within the hydraulic cavity 58 must be maintained at an hydraulic pressure which causes an upward force that is greater than a downward force on the wafer platen 34 caused by the supercritical fluid.

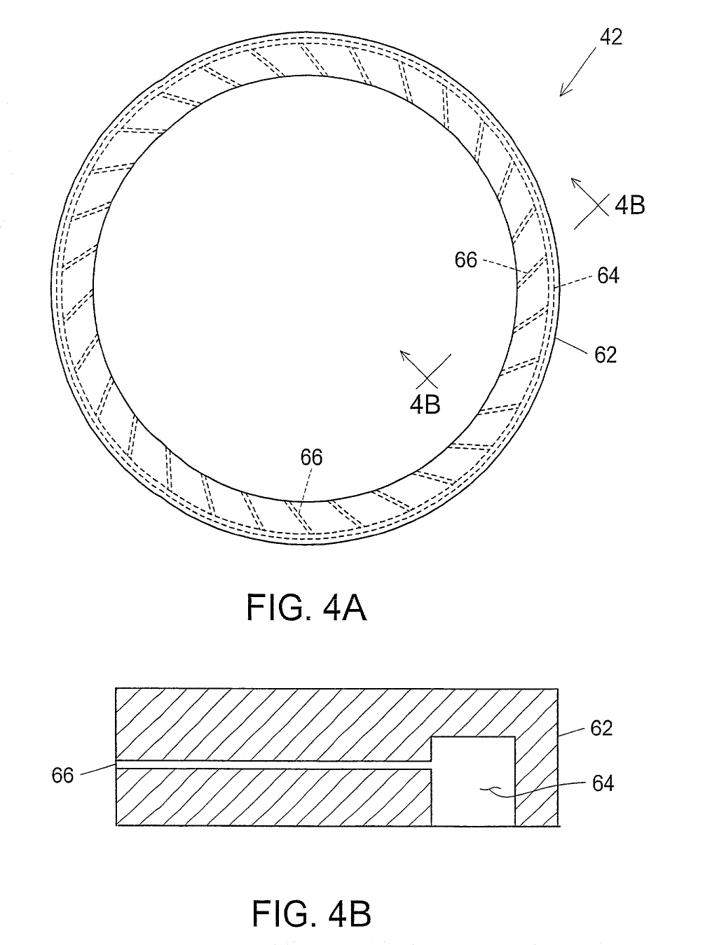

The spacer/injection ring 42 of the present invention is further illustrated FIG. 4A. The spacer/injection ring comprises a ring body 62 having a plenum 64 and injection nozzles 66. Preferably, the spacer/injection ring 42 has an inside diameter of slightly greater than 12 inches, which is sized for the 300 mm wafer. Alternatively, the spacer/injection ring 42 has a larger or smaller inside diameter. Preferably, the spacer/injection ring has forty-five of the injection nozzles 66. Alternatively, the spacer/injection ring has more or less of the injection nozzles 66. Preferably, each of the injection nozzles 66 is oriented at 45° to a radius of the inside diameter of the spacer/injection ring 42. Alternatively, the injection nozzles are at a larger or smaller angle. Preferably, the spacer/injection ring 42 has a thickness of 0.200 inches. Alternatively, the spacer/injection ring 42 has a larger or smaller thickness.

A cross-section of the spacer/injection ring 42 is illustrated in FIG. 4B, showing the ring body 62, the plenum 64, and one of the injection nozzles 66. Preferably, the plenum 64 has a rectangular cross-section having a width of 0.160 inches and a height of 0.110 inches. Preferably, each of the injection nozzles 66 has a diameter of 0.028 inches. The plenum 64 and the injection nozzles 66 of the spacer/injection ring 42 form a passage for the supercritical fluid entering the wafer cavity 44 (FIG. 3). In the supercritical processing, the supercritical fluid first enters the plenum 64, which acts as a reservoir for the supercritical fluid. The supercritical fluid is then injected into the wafer cavity 44 by the injection nozzles 66, which creates a vortex within the wafer cavity 44 (FIG. 3).

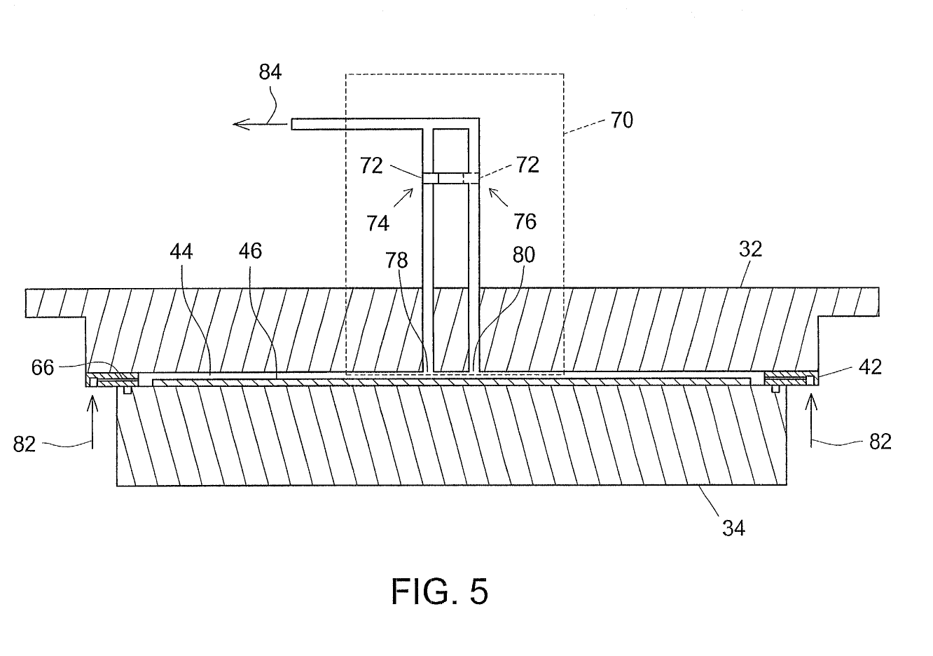

The wafer cavity 44 and a two port outlet of the present invention are illustrated in FIG. 5. The wafer cavity 44 formed by the top lid 32, the wafer platen 34, and the spacer/injection ring 42 is preferably exhausted through the two port outlet 70. The two port outlet 70 includes a shuttle piece 72, which is alternated between a first position 74 and a second position 76. By alternating the shuttle piece 72 between the first and second positions, a center of the vortex formed by the spacer/injection ring 42 will alternate between a first exhaust port 78 and a second exhaust port 80. Preferably, the first and second exhaust ports, 78 and 80, have a diameter of 0.40 inch and have centers separated by a distance of 1.55 inches. Alternatively, the diameter and the distance are larger or smaller depending upon the specific implementation of the present invention.

In operation, incoming supercritical fluid 82 enters the plenum 64 of the spacer/injection ring 42, creates the vortex within the wafer cavity 44, and alternately creates first and second vortex centers proximate to the first and second exhaust ports, 78 and 80, as the shuttle piece moves from the first position 74 to the second position 76. Outgoing supercritical fluid 84 then exits the two port outlet 70. In this way, the supercritical processing of an entire surface of the semiconductor wafer 46 is assured.

It will be readily apparent to one skilled in the art that the injection nozzles 66 of the spacer/injection ring 42 and the two port outlet 70 can be incorporated into a general pressure chamber having ingress and egress for a semiconductor substrate through a gate valve. Further, it will be readily apparent to one skilled in the art that the shuttle piece 72 of the two port outlet 70 can be replaced by a more general valve arrangement. Moreover, it will be readily apparent to one skilled in the art that additional outlet ports can be added to the two port outlet 70.

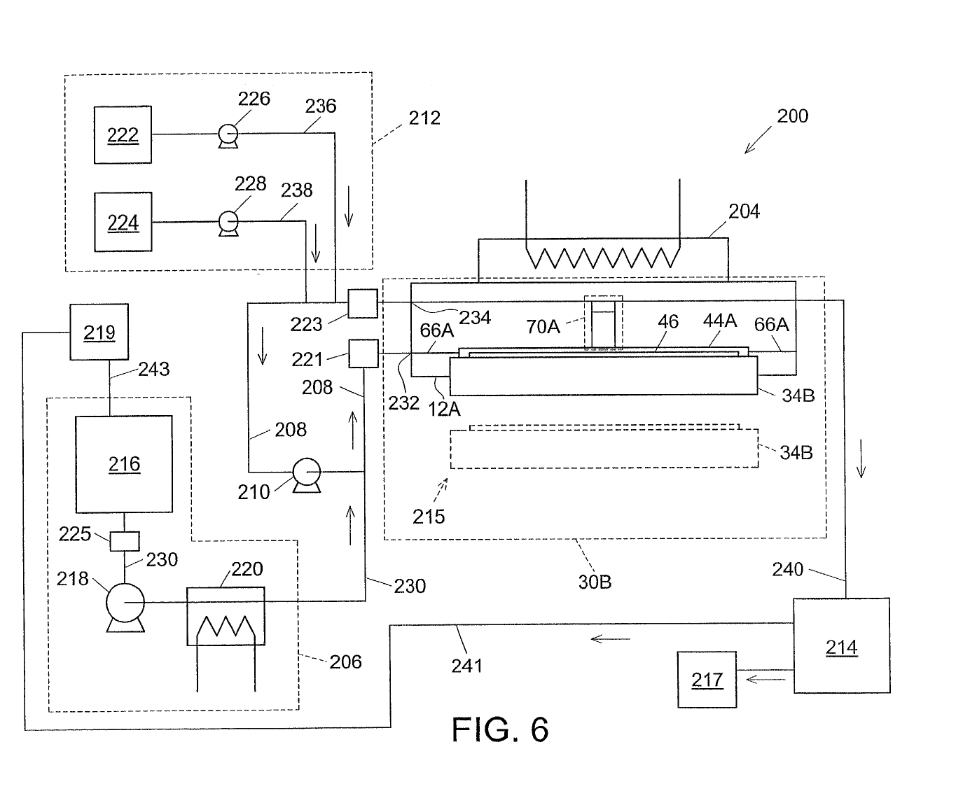

The supercritical processing module of the present invention, incorporating a second alternative pressure chamber of the present invention, is illustrated in FIG. 6. The supercritical processing module 200 includes the second alternative pressure chamber 30B, a pressure chamber heater 204, a carbon dioxide supply arrangement 206, a circulation loop 208, a circulation pump 210, a chemical agent and rinse agent supply arrangement 212, a separating vessel 214, a liquid/solid waste collection vessel 217, and a liquefying/purifying arrangement 219.

The second alternative pressure chamber 30B includes an alternative pressure chamber housing 12A and an alternative wafer platen 34B. The alternative pressure chamber housing 12A and the alternative wafer platen 34B form a first alternative wafer cavity 44A for the semiconductor substrate 46. The alternative pressure chamber housing 12A includes alternative injection nozzles 66A and an alternative two port outlet 70A. Preferably, the alternative wafer platen 34B is held against the alternative pressure chamber housing 12A using a hydraulic force. Alternatively, the alternative wafer platen 34B is held against the alternative pressure chamber housing 12A using a mechanical clamping force. Preferably, the alternative wafer platen 34B moves to a load/unload position 215 by releasing the hydraulic force. Alternatively, the alternative wafer platen 34B moves to the load/unload position 215 upon release of the mechanical clamping force. Further alternatively, the alternative wafer platen 34B moves to the load/unload position 215 by actuating a drive screw coupled to the alternative wafer platen 34B or by using a pneumatic force.

The carbon dioxide supply arrangement 206 includes a carbon dioxide supply vessel 216, a carbon dioxide pump 218, and a carbon dioxide heater 220. The chemical agent and rinse agent supply arrangement 212 includes a chemical supply vessel 222, a rinse agent supply vessel 224, and first and second high pressure injection pumps, 226 and 228.

The carbon dioxide supply vessel 216 is coupled to the second alternative pressure chamber 30B via the carbon dioxide pump 218 and carbon dioxide piping 230. The carbon dioxide piping 230 includes the carbon dioxide heater 220 located between the carbon dioxide pump 218 and the second alternative pressure chamber 30B. The pressure chamber heater 204 is coupled to the second alternative pressure chamber 30B. The circulation pump 210 is located on the circulation loop 208. The circulation loop 208 couples to the second alternative pressure chamber 30B at a circulation inlet 232 and at a circulation outlet 234. The chemical supply vessel 222 is coupled to the circulation loop 208 via a chemical supply line 236. The rinse agent supply vessel 224 is coupled to the circulation loop 208 via a rinse agent supply line 238. The separating vessel 214 is coupled to the second alternative pressure chamber 30B via exhaust gas piping 240. The liquid/solid waste collection vessel 217 is coupled to the separating vessel 214.

The separating vessel 214 is preferably coupled to the liquefying/purifying arrangement 219 via return gas piping 241. The liquefying/purifying arrangement 219 is preferably coupled to the carbon dioxide supply vessel 216 via liquid carbon dioxide piping 243. Alternatively, an off-site location houses the liquefying/purifying arrangement 219, which receives exhaust gas in gas collection vessels and returns liquid carbon dioxide in liquid carbon dioxide vessels.

The pressure chamber heater 204 heats the second alternative pressure chamber 30B. Preferably, the pressure chamber heater 204 is a heating blanket. Alternatively, the pressure chamber heater is some other type of heater.

Preferably, first and second filters, 221 and 223, are coupled to the circulation loop 208. Preferably, the first filter 221 comprises a fine filter. More preferably, the first filter 221 comprises the fine filter configured to filter 0.05 μm and larger particles. Preferably, the second filter 223 comprises a coarse filter. More preferably, the second filter 223 comprises the coarse filter configured to filter 2-3 μm and larger particles. Preferably, a third filter 225 couples the carbon dioxide supply vessel 216 to the carbon dioxide pump 218. Preferably, the third filter 225 comprises the fine filter. More preferably, the third filter 225 comprises the fine filter configured to filter the 0.05 μm and larger particles.

It will be readily apparent to one skilled in the art that the supercritical processing module 200 includes valving, control electronics, and utility hookups which are typical of supercritical fluid processing systems. Further, it will be readily apparent to one skilled in the art that the alternative injection nozzles 66A could be configured as part of the alternative wafer platen 34B rather than as part of the alternative chamber housing 12A.

In operation, the supercritical processing module is preferably used for removing the photoresist and photoresist residue from the semiconductor wafer 46. A photoresist removal process employing the supercritical processing module 200 comprises a loading step, a cleaning procedure, a rinsing procedure, and an unloading step.

In the loading step, the semiconductor wafer 46 is placed on the alternative wafer platen 34B and then the alternative wafer platen 34B is moved against the alternative chamber housing 12A sealing the alternative wafer platen 34B to the alternative chamber housing 12A and, thus, forming the first alternative wafer cavity 44A.

The cleaning procedure comprises first through fourth process steps. In the first process step, the first alternative wafer cavity 44A is pressurized by the carbon dioxide pump 218 to desired supercritical conditions. In the second process step, the first injection pump 226 pumps solvent form the chemical supply vessel 222 into the first alternative wafer cavity 44A via the chemical supply line and the circulation loop 208. Upon reaching desired supercritical conditions, the carbon dioxide pump stops pressurizing the first alternative wafer cavity 44A. Upon reaching a desired concentration of the solvent, the first injection pump 226 stops injecting the solvent. In the third process step, the circulation pump 210 circulates supercritical carbon dioxide and the solvent through the first alternative wafer cavity 44A and the circulation loop 208 until the photoresist and the photoresist residue is removed from the semiconductor wafer. In the fourth process step, the wafer cavity 44A is partially exhausted while maintaining pressure above a critical pressure, then the first alternative wafer cavity 44A is re-pressurized by the carbon dioxide pump 218 and partially exhausted again while maintaining the pressure above the critical pressure.

The rinsing procedure comprises fourth through seventh process steps. In the fourth process step, the first alternative wafer cavity is pressurized by the carbon dioxide pump 218. In the fifth process step, the second injection pump 228 pumps a rinse agent form the rinse agent supply vessel 224 into the first alternative wafer cavity 44A via the rinse agent supply line 238 and the circulation loop 208. Upon reaching a desired concentration of the rinse agent, the second injection pump 228 stops injecting the rinse agent. In the sixth process step, the circulation pump 210 circulates the supercritical carbon dioxide and the rinse agent through the first alternative wafer cavity 44A and the circulation loop 208 for a pre-determined time. In the seventh process step, the first alternative wafer cavity 44A is de-pressurized. Alternatively, it may be found that the fifth and sixth process steps are not needed.

In the unloading step, the alternative wafer platen 34B is moved to the load/unload position 215 where the semiconductor is removed from the alternative wafer platen 34B.

Preferably, at least two of the supercritical processing modules of the present invention form part of a multiple workpiece processing system, which provides simultaneous processing capability for at least two of the semiconductor wafers. The multiple workpiece processing system is taught in U.S. patent application Ser. No. 09/704,642, filed on Nov. 1, 2000, which is incorporated in its entirety by reference. Alternatively, the supercritical processing module of the present invention along with a non-supercritical processing module forms part of a multiple process semiconductor processing system. The multiple process semiconductor processing system is taught in U.S. patent application Ser. No. 09/704,641, filed Nov. 1, 2000, which is incorporated in its entirety by reference. Further alternatively, the supercritical processing module of the present invention forms part of a stand-alone supercritical processing system employing a single supercritical processing module of the present invention.

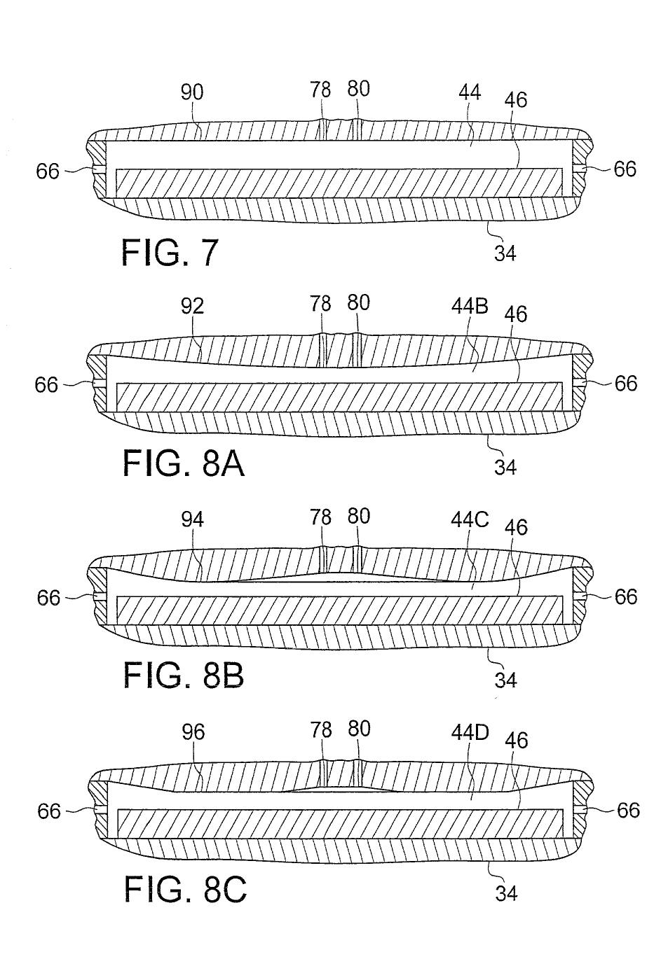

The wafer cavity 44 of the first alternative pressure chamber 30 of the present invention is further illustrated in FIG. 7. (Note that in FIG. 7, a horizontal scale has been shortened by a factor of 0.75 and a vertical scale has been expanded by a factor of four relative to the horizontal and vertical scales used in FIGS. 3 and 5.) An upper surface 90 of the wafer cavity 44 comprises a flat surface. Based on computational fluid dynamics, it has been found that the flat surface provides molecular speeds across the semiconductor wafer 46 which vary from a maximum at an outer edge of the semiconductor wafer 46 to a minimum about halfway between the outer edge and a center of the semiconductor wafer 46. Near the center of the semiconductor wafer 46, the flat surface provides molecular speeds intermediate between the minimum and maximum. For some applications this variation in the molecular speeds is acceptable. But in other applications, more uniform molecular speeds are preferred to ensure that a sufficient molecular speed is present to remove particulates. Second through fourth alternative wafer cavities of the present invention provide the more uniform molecular speeds that are sometimes needed.

The second alternative wafer cavity of the present invention is illustrated in FIG. 8A. The second alternative wafer cavity 44B comprises a first alternative upper surface 92. The first alternative upper surface 92 comprises a height variation from a maximum at an outer diameter of the second alternative wafer cavity 44B to a minium at a center of the second alternative wafer cavity 44B. Based on computational fluid dynamics, it has been found that the first alternative upper surface 92 provides molecular speeds across the semiconductor wafer 46 which are more uniform and higher than molecular speeds provided by the flat surface. However, at the center of the semiconductor wafer 46 the molecular speeds are higher than elsewhere across the semiconductor wafer 46.

The third alternative wafer cavity of the present invention is illustrated in FIG. 8B. The third alternative wafer cavity 44C comprises a second alternative upper surface 94. The second alternative upper surface 94 comprises a continuous height variation from a maximum at an outer diameter of the third alternative wafer cavity 44C through a minimum at a point proximately midway between the outer diameter and a center of the third alternative wafer cavity 44C to an intermediate height at a center of the third alternative wafer cavity 44C. Based on computational fluid dynamics, it has been found that the second alternative upper surface 94 provides molecular speeds across the semiconductor wafer 46 which are more uniform than with the first alternative upper surface 92.

The fourth alternative wafer cavity of the present invention is illustrated in FIG. 8C. The fourth alternative wafer cavity 44D comprises a third alternative upper surface 96. The third alternative upper surface 96 comprises a discontinuous height variation which approximates the continuous height variation of second alternative upper surface 94. The discontinuous height variation begins with a maximum height at an outer edge of the fourth alternative wafer cavity 44D and ramps to a minium height part way into the fourth alternative wafer cavity 44D. The discontinuous height variation continues toward a center of the fourth alternative wafer cavity 44D at the minimum height and then returns to the maximum near the center of the fourth alternative wafer cavity 44D. Based on computational fluid dynamics, it has been found that the third alternative upper surface 96 provides molecular speeds across the semiconductor wafer 46 which are more uniform than molecular speeds provided by the first alternative upper surface 92 but not as uniform as the molecular speeds provided by the second alternative upper surface 94. However, an advantage of the third alternative upper surface 96 over the second alternative upper surface 94 is that the third alternative upper surface 96 is easier to fabricate.

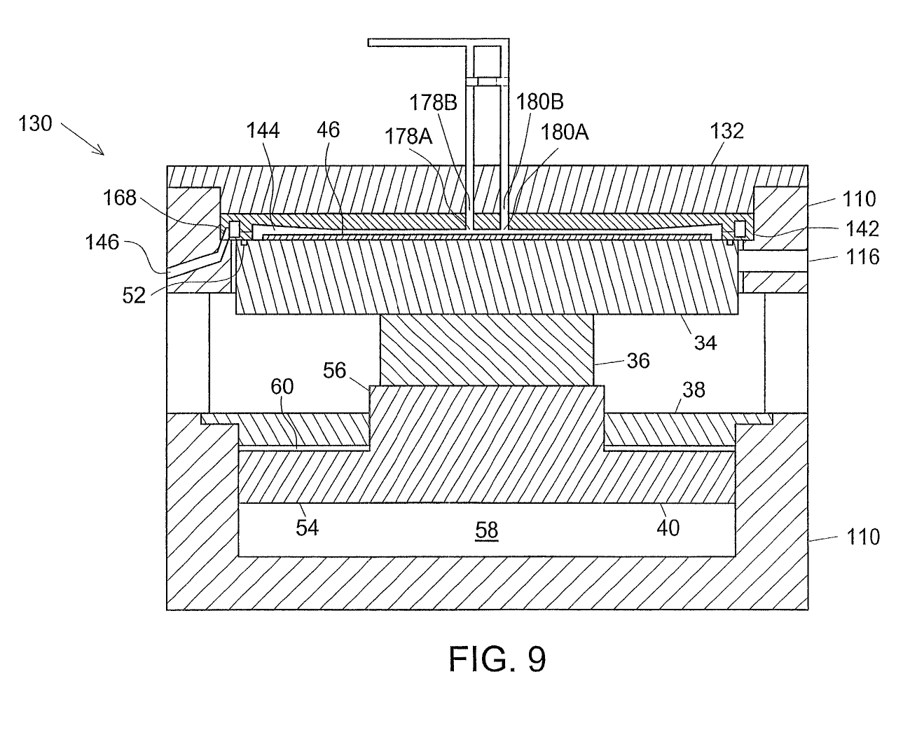

The preferred pressure chamber of the present invention is illustrated in FIG. 9. The preferred pressure chamber 130 comprises a second pressure chamber frame 110, a second top lid 132, the wafer platen 34, the cylinder 36, the sealing plate 38, the piston 40, and an upper cavity plate/injection ring 142. The wafer platen 34 and the upper cavity plate/injection ring 142 form the preferred wafer cavity 144. The third o-ring (not shown) located in third o-ring groove 52 seals the preferred wafer cavity 144. The second pressure chamber frame 110 comprises an inlet conduit 146. The inlet conduit 146 couples to an injection ring inlet port 168. A first c-seal (not shown) seals a first interface between the inlet conduit 146 and the injection ring inlet port 168. The upper cavity plate/injection ring 142 comprise third and fourth outlet ports, 178A and 180A, which couple to fifth and sixth outlet ports, 178B and 180B of the second top lid 132. Second and third c-seals (not shown) seal second and third interfaces between the third and fifth outlet ports, 178A and 178B, and the fourth and sixth outlet ports, 180A and 180B, respectively.

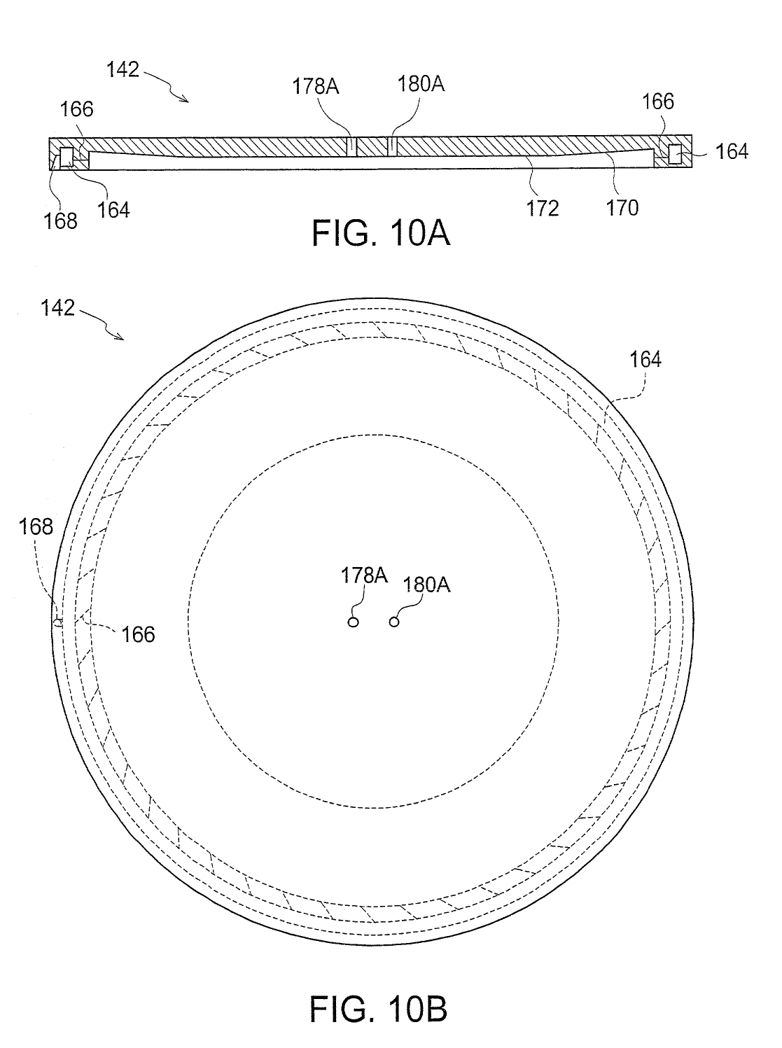

The upper cavity plate/injection ring 142 of the present invention is further illustrated in FIGS. 10A and 10B. The upper cavity plate/injection ring 142 comprises a second plenum 164, second injection nozzles 166, the injection ring inlet port 168, the fifth and sixth outlet ports, 178A and 180A, and a second discontinuous height variation feature. The second discontinuous height variation feature comprises a decreasing height feature 170 and a uniform height feature 172. The decreasing height feature 170 is located proximate to an outer diameter region of the upper cavity plate/injection ring 142. The uniform height feature 172 is located proximate to an inner diameter region of the upper cavity plate/injection ring 142.

Preferably, the upper cavity plate/injection ring 142 is fabricated by welding an outer ring to a plate. The outer ring comprises the second plenum 164. The plate comprises the second injection nozzles 166. Preferably, the outer ring and the plate comprise 316L stainless steel.

It will be readily apparent to one skilled in the art that the preferred pressure chamber 130 and the first and second alternative pressure chambers, 30 and 30B, of the present invention are appropriate for high pressure processing that is below supercritical conditions.

It will be readily apparent to one skilled in the art that other various modifications may be made to the preferred embodiment without departing from the spirit and scope of the invention as defined by the appended claims.

We claim:

1. A high pressure chamber for processing of a semiconductor substrate comprising:
a. a high pressure processing cavity for the semiconductor substrate;
b. a plurality of injection nozzles oriented into the high pressure processing cavity at a vortex angle, the plurality of injection nozzles operable to produce a vortex over a surface of the semiconductor substrate; and
c. first and second outlet ports located proximate to a center of the plurality of injection nozzles, the first and second outlet ports operable in a first time segment to provide an operating outlet out of the first outlet port and operable in a second time segment to provide the operating outlet out of the second outlet port.

2. The high pressure processing chamber of claim 1 wherein the high pressure processing cavity comprises a semiconductor substrate holding surface, an outlet port surface opposite to the semiconductor wafer holding surface, and a cylindrical surface coupling the semiconductor substrate holding surface to the outlet port surface.

3. The high pressure processing chamber of claim 2 wherein the cylindrical surface includes the plurality of injection nozzles.

4. The high pressure processing chamber of claim 2 wherein the outlet port surface includes the first and second outlet ports.

5. The high pressure processing chamber of claim 4 wherein the high pressure processing cavity comprises a proximately uniform distance between the semiconductor substrate holding surface and the outlet port surface.

6. The high pressure processing chamber of claim 4 wherein the high pressure processing cavity comprises a non-uniform distance between the semiconductor substrate holding surface and the outlet port surface.

7. The high pressure processing chamber of claim 6 wherein the non-uniform distance comprises a maximum at an outer edge of the outlet port surface and a minimum at a center of the outlet port surface.

8. The high pressure processing chamber of claim 6 wherein the non-uniform distance comprises a first distance at an outer edge of the outlet port surface, a second distance at an intermediate position between the outer edge and a center of the outlet port surface, and a third distance at the center of the outlet port surface, and further wherein the first distance and the third distance are each greater than the second distance.

9. A high pressure chamber for processing of a semiconductor substrate comprising:
a. a high pressure processing cavity comprising a semiconductor substrate holding surface, an outlet port surface opposite to the semiconductor wafer holding surface, and a cylindrical surface coupling the semiconductor substrate holding surface to the outlet port surface;
b. a plurality of injection nozzles located in the cylindrical surface and oriented at a vortex angle, the plurality of injection nozzles operable to produce a vortex over a surface of the semiconductor substrate; and
c. first and second outlet ports located in the outlet port surface proximate to a center of the plurality of injection nozzles, the first and second outlet ports operable in a first time segment to provide an operating outlet out of the first outlet port and operable in a second time segment to provide the operating outlet out of the second outlet port.

10. A high pressure chamber for processing of a semiconductor substrate comprising:
a. a high pressure processing cavity comprising a semiconductor substrate holding surface, an outlet port surface opposite to the semiconductor wafer holding surface, and a cylindrical surface coupling the semiconductor substrate holding surface to the outlet port surface, the high pressure processing cavity comprising a non-uniform distance between the semiconductor substrate holding surface and the outlet port surface, the non-uniform distance comprising a first distance at an outer edge of the outlet port surface, a second distance at an intermediate position between the outer edge and a center of the outlet port surface, and a third distance at the center of the outlet port surface, where the first distance and the third distance are each greater than the second distance;
b. a plurality of injection nozzles located in the cylindrical surface and oriented at a vortex angle, the plurality of injection nozzles operable to produce a vortex over a surface of the semiconductor substrate; and
c. first and second outlet ports located in the outlet port surface proximate to a center of the plurality of injection nozzles, the first and second outlet ports operable in a first time segment to provide an operating outlet out of the first outlet port and operable in a second time segment to provide the operating outlet out of the second outlet port.
